(19) United States
(12) Patent Application Publication
(10) Pub. No.: US 2024/0376604 A1
(43) Pub. Date: Nov. 14, 2024

(54) SUBSTRATE PROCESSING APPARATUS

(71) Applicant: Samsung Electronics Co., Ltd., Suwon-si (KR)

(72) Inventors: Hyunjoong Kim, Suwon-si (KR); Jongchan Lee, Pyeongtaek-si (KR); Junho Lee, Pyeongtaek-si (KR); Jinman Park, Pyeongtaek-si (KR); Sengyeop Kim, Pyeongtaek-si (KR); Youngjoo Kim, Suwon-si (KR); Seounghwan Byun, Suwon-si (KR); Hana Seu, Suwon-si (KR); Sunjoo Lee, Suwon-si (KR); Cheoljae Lee, Suwon-si (KR); Dongchul Choi, Pyeongtaek-si (KR)

(73) Assignees: Samsung Electronics Co., Ltd., Suwon-si (KR); Mecaro Co., Ltd., Pyeongtaek-si (KR)

(21) Appl. No.: 18/660,546

(22) Filed: May 10, 2024

(30) Foreign Application Priority Data
May 11, 2023 (KR) 10-2023-0061352
Aug. 14, 2023 (KR) 10-2023-0106418

(51) Int. Cl. C23C 16/46; H01J 37/32

(52) U.S. Cl. CPC C23C 16/46; H01J 37/32201; H01J 37/3244

(57) ABSTRACT

A substrate processing apparatus includes a processing chamber including a processing space where a substrate is processed and a heater provided in the process chamber to support the substrate and configured to heat the substrate, wherein the heater includes a body, a first protrusion portion protruding upward in a vertical direction from a center of the body, and a second protrusion portion protruding upward from a center of the first protrusion portion, first embossings are formed in a region which does not overlap the first protrusion portion in a vertical direction on an upper surface of the body, second embossings are formed in a region which does not overlap the second protrusion portion in a vertical direction on an upper surface of the first protrusion portion, and third embossings are formed on an upper surface of the second protrusion portion.

### CROSS-REFERENCE TO RELATED APPLICATION

This application is based on and claims priority under 35 U.S.C. § 119 to Korean Patent Application No. 10-2023-0061352, filed on May 11, 2023, and 10-2023-0106418, filed on Aug. 14, 2023, in the Korean Intellectual Property Office, the disclosures of which are incorporated by reference herein in their entirety.

### BACKGROUND

Aspects of the inventive concept relate to a substrate processing apparatus, and more particularly, to a substrate processing apparatus which applies heat to a substrate.

Generally, semiconductor devices are manufactured from a substrate such as a wafer. In detail, semiconductor devices are manufactured by forming a fine circuit pattern on an upper surface of a substrate through a deposition process, a photolithography process, and an etching process. While such a process is being performed, a substrate may be heated by a heater.

### SUMMARY

Aspects of the inventive concept provide a substrate processing apparatus which minimizes a problem occurring in heating a substrate with a heater.

The object of the inventive concept is not limited to the aforesaid, but other objects not described herein will be clearly understood by those of ordinary skill in the art from descriptions below.

To solve such a problem, the following substrate processing apparatus may be provided.

According to an aspect of the inventive concept, there is provided a substrate processing apparatus including a processing chamber including a processing space where a substrate is processed and a heater provided in the process chamber to support a lower surface of the substrate and configured to heat the substrate, wherein the heater includes a body, a first protrusion portion protruding upward in a vertical direction from a center of the body, and a second protrusion portion protruding upward in a vertical direction from a center of the first protrusion portion, first embossings formed in a region which does not overlap the first protrusion portion in a vertical direction on an upper surface of the body, second embossings formed in a region which does not overlap the second protrusion portion in a vertical direction on an upper surface of the first protrusion portion, and third embossings formed on an upper surface of the second protrusion portion.

According to another aspect of the inventive concept, there is provided a substrate processing apparatus including a processing chamber including a processing space where a substrate is processed, a body provided in the process chamber to have a circular plate shape, a first protrusion portion protruding upward in a vertical direction from a center region of the body, a second protrusion portion protruding upward in a vertical direction from a center region of the first protrusion portion, first embossings protruding upward in a vertical direction in a region which does not overlap the first protrusion portion in a vertical direction on an upper surface of the body, second embossings protruding upward in a vertical direction in a region which does not overlap the second protrusion portion in a vertical direction on an upper surface of the first protrusion portion, and third embossings protruding upward in a vertical direction from an upper surface of the second protrusion portion, wherein an edge region of an upper surface of each of the first embossings, the second embossings, and the third embossings has a round shape.

According to another aspect of the inventive concept, there is provided a substrate processing apparatus including a processing chamber including a processing space where a substrate is processed, a gas supply unit configured to supply a processing gas to the processing space, a microwave application unit configured to excite the processing gas to plasma, a body provided in the process chamber to have a circular plate shape, a first protrusion portion protruding upward in a vertical direction from a center region of the body, a second protrusion portion protruding upward in a vertical direction from a center region of the first protrusion portion, first embossings protruding upward in a vertical direction in a region which does not overlap the first protrusion portion in a vertical direction on an upper surface of the body, second embossings protruding upward in a vertical direction in a region which does not overlap the second protrusion portion in a vertical direction on an upper surface of the first protrusion portion, and third embossings protruding upward in a vertical direction from an upper surface of the second protrusion portion, wherein an edge region of an upper surface of each of the first embossings, the second embossings, and the third embossings has a round shape, and a curvature of a round top edge of each of the at least one first embossings, the second embossings, the third embossings is within a range of about 0.01 to about 0.016, thicknesses of the first embossings, the second embossings, and the third embossings in a vertical direction are equal to one another, a step height between the first protrusion portion and the body in a vertical direction is within a range of about 0.01 mm to about 0.04 mm, and a step height between the second protrusion portion and the first protrusion portion in a vertical direction is within a range of about 0.01 mm to about 0.04 mm.

### BRIEF DESCRIPTION OF THE DRAWINGS

Embodiments will be more clearly understood from the following detailed description taken in conjunction with the accompanying drawings in which:

FIG. 1 is a cross-sectional view schematically illustrating a substrate processing apparatus according to embodiments;

FIG. 2 is a plan view schematically illustrating a heater of the substrate processing apparatus of FIG. 1;

FIGS. 3A and 3B are cross-sectional views illustrating a temperature-based change in a region AA of a substrate processing apparatus according to embodiments;

FIG. 4 is a perspective view schematically illustrating a first embossing of the substrate processing apparatus of FIG. 1;

FIG. 5 is another cross-sectional view taken along line X1-X1′ of the first embossing of FIG. 4;

FIG. 6A is a graph showing an iron (Fe) particle density of a rear surface of a substrate before a substrate processing apparatus according to embodiments is applied, and FIG. 6B is a graph showing an Fe particle density of the rear surface of the substrate after the substrate processing apparatus according to embodiments is applied;

FIG. 7 is a cross-sectional view schematically illustrating a substrate processing apparatus according to embodiments; and

FIG. 8 is a cross-sectional view schematically illustrating a substrate processing apparatus according to embodiments.

### DETAILED DESCRIPTION OF THE EMBODIMENTS

Hereinafter, embodiments will be described in detail with reference to the accompanying drawings. Like reference numerals refer to like elements in the drawings, and their repeated descriptions are omitted.

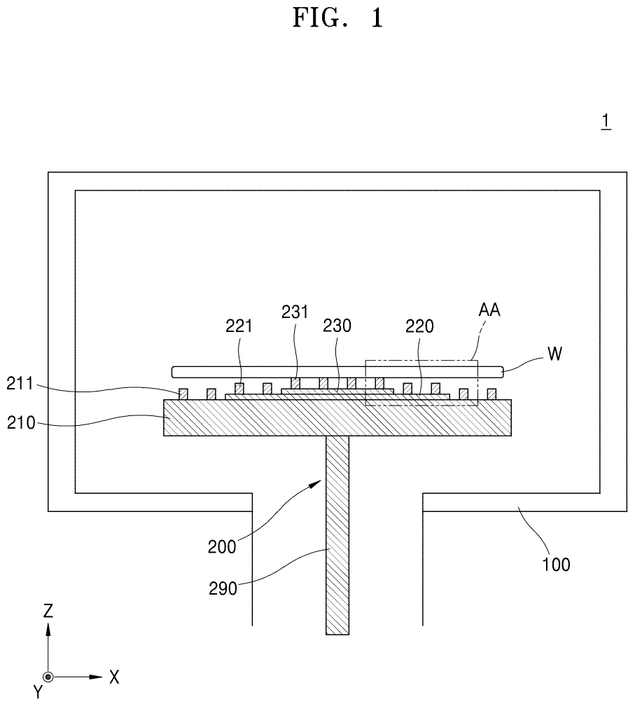

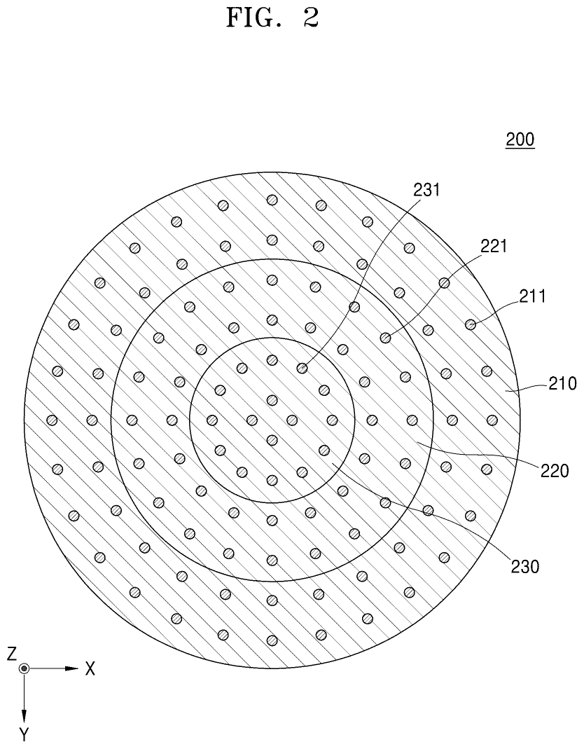

FIG. 1 is a cross-sectional view schematically illustrating a substrate processing apparatus 1 according to embodiments. FIG. 2 is a plan view schematically illustrating a heater of the substrate processing apparatus 1 of FIG. 1.

Referring to FIGS. 1 and 2, the substrate processing apparatus 1 may include a process chamber 100 and a heater 200. The process chamber 100 may include a processing space where a substrate W is processed. A vertical cross-sectional surface of the process chamber 100 may have a rectangular shape which is hollow, but is not limited thereto. A processing process of the substrate W may be performed in the process chamber 100. The processing process may include a deposition process, a photolithography process, and an etching process on the substrate W. Also, the deposition process may include a chemical vapor deposition (CVD) process, a physical vapor deposition (PVD) process, and an atomic layer deposition (ALD) process, but is not limited thereto.

The heater 200 may be disposed in the process chamber 100. According to embodiments, the heater 200 may contact a lower surface of the substrate W and may support the substrate W. A heating coil may be provided in the heater 200. The heating coil may heat at least one of a body 210, a first protrusion portion 220, a second protrusion portion 230, and first to third embossings 211, 221, and 231 of the heater 200. FIG. 1 illustrates a state in which the heater 200 is not heated. As discussed in further detail below, when the heater 200 is heated, and thermal strain occurs causing a contraction in a central region of the body 210, the first to third embossings 211, 221, and 231 may physically contact the lower surface of the substrate W. When the heated first to third embossings 211, 221, and 231 come into physical contact with the lower surface of the substrate W, the heated first to third embossings 211, 221, and 231 may heat the substrate W through conduction. Also, when the contraction of the body 210 is insufficient to result in the first embossing 211 and the second embossings 221 physically contacting the lower surface of the substrate W, the body 210, the first protrusion portion 220, the second protrusion portion 230, the first embossing 211 and the second embossing 221, which do not physically contact the substrate W, may heat the substrate W through convection.

In some embodiments, a plurality of heating coils may be provided at different positions, and each of the plurality of heating coils may be individually controlled. For example, when one heating coil emits heat, one other heating coil may not emit heat. Also, when a temperature of a certain region is higher than a temperature of a peripheral region, a heating coil disposed in the certain region may be controlled not to emit heat. Because the plurality of heating coils are provided at different positions in the heater 200, a surface of the heater 200 may have a wholly uniform temperature.

In the following drawings, an X-axis direction and a Y-axis direction may each represent a direction parallel to a surface of an upper surface or a lower surface of the substrate W, and the X-axis direction and the Y-axis direction may be directions perpendicular to each other. A Z-axis direction may represent a direction perpendicular to the surface of the upper surface or the lower surface of the substrate W. In other words, the Z-axis direction may be a direction perpendicular to an X-Y plane.

Also, in the following drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The heater 200 may include the body 210, the first protrusion portion 220, the second protrusion portion 230, and a supporter 290. According to embodiments, the body 210 may be coupled to the supporter 290 and may have a plate shape. A vertical cross-sectional surface of the body 210 may have a rectangular shape. When seen in the vertical direction Z, the body 210 may have a circular plate shape. According to embodiments, a diameter of the body 210 may be within a range of about 265 nm to about 300 nm.

The supporter 290 may be coupled to a lower surface of the body 210 and may support the body 210. In some embodiments, the supporter 290 may have a rod shape which extends in the vertical direction Z.

The first embossing 211 may be formed on an upper surface of the body 210. The first embossing 211 may have a circular pillar shape which protrudes in the vertical direction Z from the upper surface of the body 210. However, a shape of the first embossing 211 is not limited thereto, and the first embossing 211 may have an angular pillar shape which extends in the vertical direction Z.

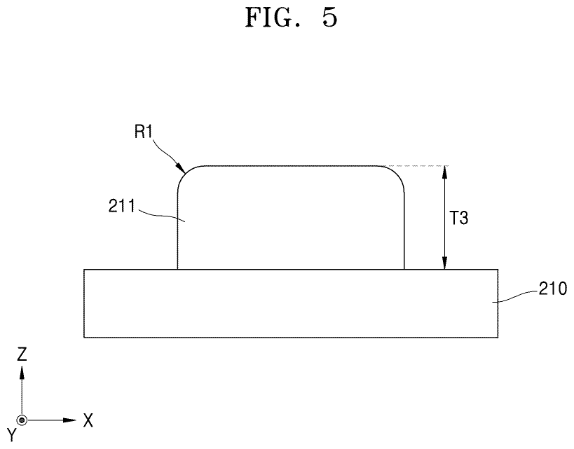

The first embossing 211 may be formed in a region which does not overlap the first protrusion portion 220 in the vertical direction Z. As discussed in further detail below, when the heater 200 is heated and a resulting contraction of the body 210 occurs, an upper surface of each of the first embossings 211 may contact the lower surface of the substrate W. In detail, the first embossings 211 may support a lower surface of an outer region of the substrate W. According to embodiments, the first embossings 211 may be disposed while forming a virtual circle along a region which does not overlap the first protrusion portion 220 in the vertical direction Z, on the upper surface of the body 210. For example, the first embossings 211 may be arranged apart from one another by a certain interval in parallel in an edge region of the upper surface of the body 210. As used herein, an “embossing” refers to a protrusion (a raised structure) extending from a surface. For example, the embossings disclosed herein may be a pattern of extrusions from a surface, such as the surface of the body 210 and a surface of the protrusion portions (e.g., first protrusion portion 220 and second protrusion portion 230). Examples of the dimensions of the embossing disclosed herein are discussed in further detail below with respect to FIG. 5.

As illustrated in FIG. 2, when viewed in a plan view, the body 210, the first protrusion portion 220, and the second protrusion portion 230 may form concentric circles. Additionally, the first embossing 211, the second embossing 221, and the third embossing 231 may form a pattern of concentric circles.

The first protrusion portion 220 may have a shape which extends upward in the vertical direction Z from a center region of the body 210. According to embodiments, the first protrusion portion 220 may have a circular plate shape. An upper surface of the first protrusion portion 220 may be disposed at a vertical level which is higher than the upper surface of the body 210. The upper surface of the first protrusion portion 220 and the upper surface of the body 210 may have a step height therebetween in the vertical direction Z. A footprint of the first protrusion portion 220 may be less than a footprint of the body 210. In the same sense, a cross-sectional area based on an X-Y plane of the first protrusion portion 220 may be less than a cross-sectional area based on an X-Y plane of the body 210. When the first protrusion portion 220 is provided in a circular plate shape, a diameter of the first protrusion portion 220 may be less than that of the body 210. According to embodiments, a diameter of the first protrusion portion 220 may be within a range of about 170 nm to about 200 nm.

The second embossing 221 may be formed on the upper surface of the first protrusion portion 220. The second embossing 221 may have a circular pillar shape which protrudes upward in the vertical direction Z from the upper surface of the first protrusion portion 220. However, a shape of the second embossing 221 is not limited thereto, and the second embossing 221 may have an angular pillar shape which extends in the vertical direction Z. According to embodiments, the second embossing 221 may have the same shape as that of the first embossing 211. As illustrated in FIG. 1, when the heater 200 is not heated, an upper surface of the second embossing 221 may be disposed at a vertical level which is higher than the upper surface of the first embossing 211, and a lower surface of the second embossing 221 may be disposed at a vertical level which is higher than the lower surface of the first embossing 211. The second embossing 221 may be provided in plurality. The second embossings 221 may be formed in a region which does not overlap the second protrusion portion 230 in the vertical direction Z, on the upper surface of the first protrusion portion 220. The second embossings 221 may be formed more inward (e.g., closer to a central region of the body 210 in a horizontal direction) than the first embossings 211. The second embossings 221 may be disposed while forming a virtual circle along a region which does not overlap the second protrusion portion 230 in the vertical direction Z, on the upper surface of the first protrusion portion 220. That is, the second embossings 221 may be arranged apart from one another by a certain interval in an edge region of the upper surface of the first protrusion portion 220. As discussed in further detail below, when the heater 200 is heated and a resulting contraction of the body 210 occurs, the second embossings 221 may contact the lower surface of the substrate W. A bottom region of the substrate W contacting the second embossings 221 may be disposed more inward (e.g., closer to a central region of the substrate W in a horizontal direction) than a bottom region of the substrate W contacting the first embossings 211.

The second protrusion portion 230 may have a shape which protrudes upward in the vertical direction Z from a center region of the first protrusion portion 220. According to embodiments, the second protrusion portion 230 may have a circular plate shape. An upper surface of the second protrusion portion 230 may be disposed at a vertical level which is higher than the upper surface of the first protrusion portion 220. The upper surface of the second protrusion portion 230 and the upper surface of the first protrusion portion 220 may have a step height therebetween in the vertical direction Z. A footprint of the second protrusion portion 230 may be less than a footprint of the first protrusion portion 220. In the same sense, a cross-sectional area based on an X-Y plane of the second protrusion portion 230 may be less than a cross-sectional area based on an X-Y plane of the first protrusion portion 220. When each of the first protrusion portion 220 and the second protrusion portion 230 is provided in a circular plate shape, a diameter of the second protrusion portion 230 may be less than a diameter of the first protrusion portion 220. The upper surface of the second protrusion portion 230 and the upper surface of the first protrusion portion 220 may have a step height therebetween in the vertical direction Z. According to embodiments, a diameter of the second protrusion portion 230 may be within a range of about 100 nm to about 124 nm.

The third embossing 231 may be formed on the upper surface of the second protrusion portion 230. The third embossing 231 may have a circular pillar shape which protrudes upward in the vertical direction Z from the upper surface of the second protrusion portion 230. However, a shape of the third embossing 231 is not limited thereto, and the third embossing 231 may have an angular pillar shape which extends in the vertical direction Z. According to embodiments, the third embossing 231 may have the same shape as that of each of the first embossing 211 and the second embossing 221. As illustrated in FIG. 1, when the heater 200 is not heated, an upper surface of the third embossing 231 may be disposed at a vertical level which is higher than the upper surface of the second embossing 221, and a lower surface of the third embossing 231 may be disposed at a vertical level which is higher than the lower surface of the second embossing 221. The third embossing 231 may be provided in plurality. The third embossings 231 may be formed on the upper surface of the second protrusion portion 230. The third embossings 231 may be formed more inward (e.g., closer to a central region of the body 210 in a horizontal direction) than the second embossings 221. The third embossings 231 may be arranged apart from one another by a certain interval. The third embossings 231 may support the lower surface of the substrate W. A bottom region of the substrate W contacting the third embossings 231 may be disposed more inward (e.g., closer to a central region of the substrate W in a horizontal direction) than a bottom region of the substrate W contacting the second embossings 221. Thicknesses of the first embossing 211, the second embossing 221, and the third embossing 231 in the vertical direction Z may be substantially equal to one another.

According to embodiments, at least one of the body 210, the first protrusion portion 220, the second protrusion portion 230, the first embossing 211, the second embossing 221, and the third embossing 231 may be formed by a post-heat annealing process. In this case, the body 210, the first protrusion portion 220, the second protrusion portion 230, the first embossing 211, the second embossing 221, and the third embossing 231 may be selectively reduced in coefficient of thermal expansion without a change in crystallinity, crystal phase, or thermal conductance. Therefore, even when the heater 200 has a certain temperature or more, a center region of the heater 200 may be less contracted or may not be contracted in a processing process of the substrate W. According to embodiments, the post-heat annealing process may be performed at about 500° C. to about 1,000° C.

The heater 200 may have a temperature of T1 for heating the substrate W. In this case, the temperature T1 may be differently formed based on the kind of processing process of the substrate W. When the heater 200 has a temperature of T1, thermal strain may occur in the heater 200. In previously known heaters, when thermal strain occurs in a heater, a phenomenon where the center region of the heater is contracted may occur. Therefore, in a previously known heater, an upper surface of the center region of the heater may be disposed at a vertical level which is lower than an upper surface of an outer region of the heater. Accordingly, the lower surface of the substrate W may be supported by the outer region of the heater, and the center region of the heater and the lower surface of the substrate W may be apart from each other in the vertical direction Z and may not contact each other. As a center region of the lower surface of the substrate W does not contact the heater and an outer region of the lower surface of the substrate W contacts the heater, a temperature of the center region of the substrate W may be lower than that of the outer region of the substrate W. In a case where a deposition process is performed on the substrate W, a deposition process of the center region of the substrate W may not better be performed than the outer region of the substrate W due to a lower temperature.

However, in the substrate processing apparatus 1 according to an embodiment of the present application, the first protrusion portion 220 may be formed in a center region of the body 210 and the second protrusion portion 230 may be formed in a center region of the first protrusion portion 220, and thus, a step height may be formed on the upper surface of the heater 200. Accordingly, before the heater 200 is heated at the temperature T1, the upper surface of the heater 200 may have a vertical level which increases progressively toward a center thereof. Therefore, when the center region of the heater 200 is contracted in the vertical direction because the heater 200 has the temperature T1 and a thermal strain of the heater 200 occurs due to the temperature T1, a vertical level difference between an upper surface of the center region of the heater 200 and an upper surface of the outer region of the heater 200 may be reduced or be equal to each other, based on a step height formed by the body 210, the first protrusion portion 220, and the second protrusion portion 220. As a result, the center region of the heater 200 as well as the outer region of the heater 200 may contact the lower surface of the substrate W, and thus, the heater 200 may uniformly heat the lower surface of the substrate W.

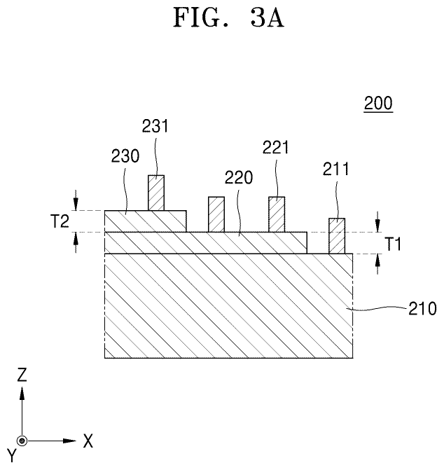

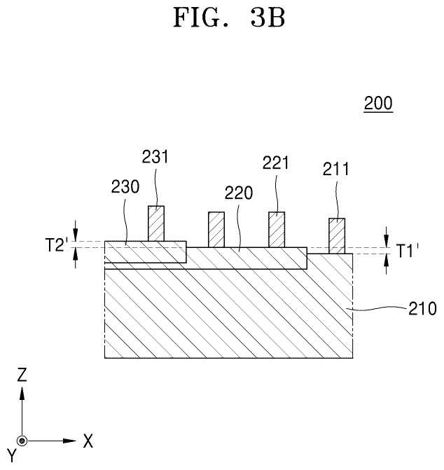

FIGS. 3A and 3B are cross-sectional views illustrating a temperature-based change in a region AA of a substrate processing apparatus according to embodiments of the present application. Hereinafter, descriptions which are the same as or similar to the descriptions of FIGS. 1 and 2 are omitted.

Referring to FIGS. 3A and 3B, before a heater 200 is heated, a body 210, a first protrusion portion 220, and a third protrusion portion 230 may have a staircase shape as illustrated in FIG. 3A. In this case, the body 210 and the first protrusion portion 220 may have a step height T1 in a vertical direction Z, and the first protrusion portion 220 and the third protrusion portion 230 may have a step height T2 in the vertical direction Z. According to embodiments, the step height T1 between the body 210 and the first protrusion portion 220 in the vertical direction Z may be substantially the same as the step height T2 between the first protrusion portion 220 and the third protrusion portion 230 in the vertical direction Z.

On the other hand, when the heater 200 is heated at a certain temperature or more, the body 210, the first protrusion portion 220, and the third protrusion portion 230 may have a shape where a center portion of the heater 200 is contracted as illustrated in FIG. 3B. In this case, the body 210 and the first protrusion portion 220 may have a step height T1′ in the vertical direction Z, and the first protrusion portion 220 and the third protrusion portion 230 may have a step height T2′ in the vertical direction Z.

In some embodiments, before the heater 200 is heated, a sum of the step height T1 between the body 210 and the first protrusion portion 220 in the vertical direction Z and the step height T2 between the first protrusion portion 220 and the third protrusion portion 230 in the vertical direction Z may be substantially the same as the degree to which the center region of the heater 200 is contracted when the heater 200 is heated to reach a certain temperature. For example, when the heater 200 reaches about 4.5° C., in a case where the center region of the heater 200 is contracted by about 0.1 mm, the sum of the step height T1 between the body 210 and the first protrusion portion 220 in the vertical direction Z and the step height T2 between the first protrusion portion 220 and the third protrusion portion 230 in the vertical direction Z may be about 0.1 mm. In this case, when the heater 200 reaches a certain temperature, the step height T1′ between the body 210 and the first protrusion portion 220 in the vertical direction Z and the step height T2′ between the first protrusion portion 220 and the third protrusion portion 230 in the vertical direction Z may each be 0.

In some embodiments, the degree to which the center region of the heater 200 is contracted may differ from the sum of the step height T1 between the body 210 and the first protrusion portion 220 in the vertical direction Z and the step height T2 between the first protrusion portion 220 and the third protrusion portion 230 in the vertical direction Z. Therefore, when the heater 200 reaches a certain temperature, each of the step height T1′ between the body 210 and the first protrusion portion 220 in the vertical direction Z and the step height T2′ between the first protrusion portion 220 and the third protrusion portion 230 in the vertical direction Z may not be 0. However, even in this case, a vertical level difference between the upper surface of the center region of the heater 200 and the upper surface of the outer region of the heater 200 may be reduced, and thus, the heater 200 may uniformly heat the lower surface of the substrate W.

In some embodiments, a step height between the body 210 and the first protrusion portion 220 in the vertical direction Z may be within a range of about 0.01 mm to about 0.04 mm. Also, a step height between the first protrusion portion 220 and the third protrusion portion 230 in the vertical direction Z may be within a range of about 0.01 mm to about 0.04 mm.

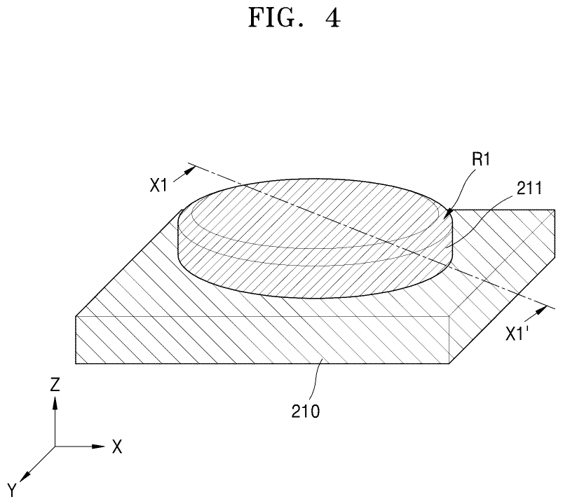

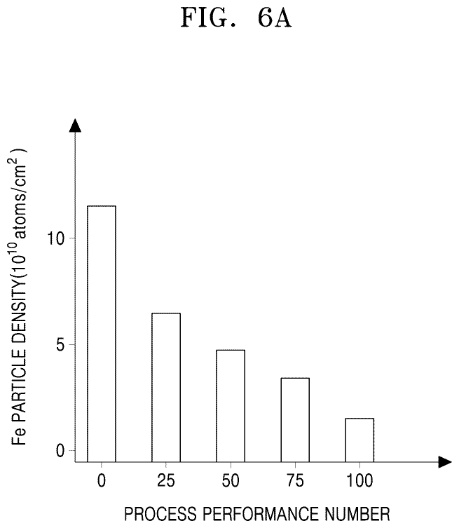

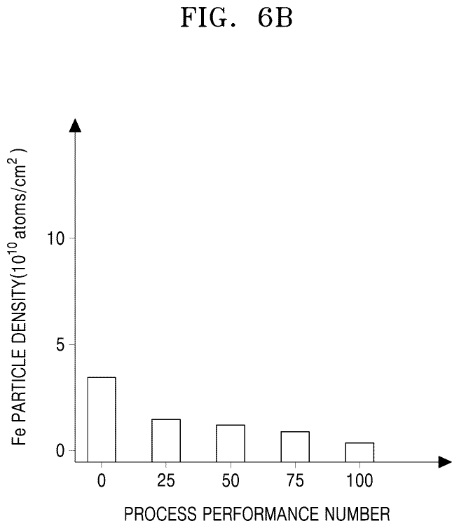

FIG. 4 is a perspective view schematically illustrating a first embossing of the substrate processing apparatus 1 of FIG. 1. FIG. 5 is another cross-sectional view taken along line X1-X1′ of the first embossing of FIG. 4. FIG. 6A is a graph showing an iron (Fe) particle density of a rear surface of a substrate before a substrate processing apparatus according to embodiments is applied, and FIG. 6B is a graph showing an Fe particle density of the rear surface of the substrate after the substrate processing apparatus according to embodiments is applied. Hereinafter, descriptions which are the same as or similar to the descriptions of FIGS. 1 to 3B are omitted. Also, in FIGS. 4 and 5, only a first embossing 211 formed on a body 210 is illustrated, but the following description may be substantially identically or similarly applied to a second embossing 221 formed on a first protrusion portion 220 and a third embossing 231 formed on a second protrusion portion 230.

Referring to FIGS. 4 and 5, the first embossing 211 may be formed to have a shape which protrudes upward in a vertical direction Z from an upper surface of the body 210. A thickness T3 of the first embossing 211 in the vertical direction Z may be within a range of about 0.1 mm to about 0.2 mm. An edge region R1 of an upper surface of the first embossing 211 may have a round shape. An upper end of the first embossing 211 may have a shape where a horizontal width increases as a level in the vertical direction Z decreases. In a case where the edge region R1 of the upper surface of the first embossing 211 has a round shape, friction between a lower surface of a substrate W and the first embossing 211 occurring when the first embossing 211 supports the substrate W may be reduced. As friction between the lower surface of the substrate W and the first embossing 211 is reduced, particles occurring in the lower surface of the substrate W may decrease. The particles may include, for example, an Fe particle and a nickel (Ni) particle.

According to embodiments, a curvature of a round edge region R1 of the first embossing 211 may be within a range of about 0.01 to about 0.016. When the curvature of the round edge region R1 of the first embossing 211 is within the range described above, friction between the first embossing 211 and the substrate W may decrease, and the number of particles occurring in the lower surface of the substrate W may further decrease. When a top edge region R1 of the first embossing 211 is not rounded, a density of initial Fe particles occurring in the lower surface of the substrate W may be about 11.62·10¹⁰ atoms/cm² as illustrated in FIG. 6A. However, when the top edge region R1 of the first embossing 211 is rounded and has a curvature having a range of about 0.01 to about 0.016, a density of initial Fe particles occurring in the lower surface of the substrate W may be about 3.25·10¹⁰ atoms/cm² as illustrated in FIG. 6B. Also, as the number of substrates W processed by performing a process increases, the upper surface of the first embossing 211 may be worn, and thus, a density of Fe particles occurring in the lower surface of the substrate W may be reduced. Even in this case, when the top edge region R1 of the first embossing 211 is rounded and has a curvature having a range of about 0.01 to about 0.016, a density of occurrence of Fe particles may be far more reduced than a case where the top edge region R1 of the first embossing 211 is not rounded. Also, a density of occurrence of Ni particles as well as a density of occurrence of Fe particles occurring in the lower surface of the substrate W may be lowered.

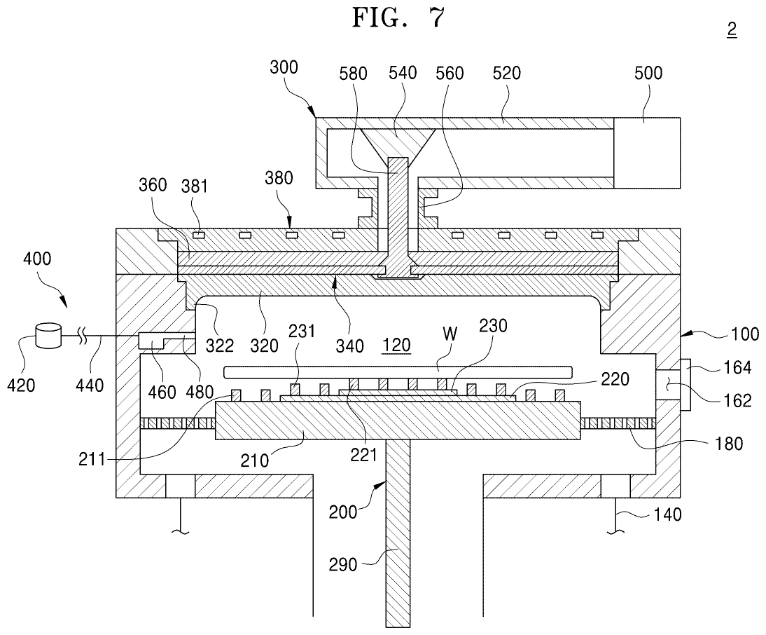

FIG. 7 is a cross-sectional view schematically illustrating a substrate processing apparatus 2 according to embodiments. Hereinafter, descriptions of the substrate processing apparatus 2 of FIG. 7, which are the same as or similar to the descriptions of the substrate processing apparatus 1 described above with reference to FIGS. 1 to 3, are omitted, and a difference therebetween will be mainly described.

Referring to FIG. 7, the substrate processing apparatus 2 may include a process chamber 100, a heater 200, a microwave application unit 300, and a gas supply unit 400. The process chamber 100 may include a processing space 120 where a substrate is processed. An entrance 162 through which a substrate W is loaded or unloaded may be formed in a sidewall of the process chamber 100. The entrance 162 may be opened or closed by a door 164.

The heater 200 may support the substrate W in the processing space 120. According to embodiments, the lower surface of the substrate W may contact the first embossing 211, the second embossing 221, and the third embossing 231 each formed in the heater 200.

In some embodiments, the heater 200 may support the substrate W with an electrostatic force. Optionally, the heater 200 may support the substrate W through mechanical clamping. A heating member for heating the substrate W may be provided in the heater 200. In some embodiments, the heating member may be provided as a heating coil which is disposed in the heater 200.

The gas supply unit 400 may supply a processing gas to the processing space 120. The processing gas may include hydrogen. The gas supply unit 400 may include a gas supply source 420 and a gas supply line 440. The gas supply source 420 may be coupled to a sidewall of the process chamber 100 by the gas supply line 440. In some embodiments, a buffer space 460 having a ring shape may be provided in the sidewall of the process chamber 100, and the gas supply line 440 may supply the processing gas to the buffer space 460. A discharge line 480, which extends from the buffer space 460 and discharges a gas to the processing space 120, may be formed in the sidewall of the process chamber 100. The discharge line 480 may be provided in plurality along a perimeter of the sidewall of the process chamber 100.

An exhaust line 140 may be connected with a lower wall of the process chamber 100. A pump may be connected with the exhaust line 140. The pump may be configured to adjust pressure of the processing space 120 to a predetermined process pressure. An exhaust baffle 180 having a ring shape may be provided at a side portion of the heater 200, in the processing space 120. An inner surface of the exhaust baffle 180 may contact the heater 200, and an outer surface of the exhaust baffle 180 may contact a sidewall of the process chamber 100. A gas may be uniformly exhausted from an upper space of the exhaust baffle 180 to a lower space thereof by the exhaust baffle 180.

The microwave application unit 300 may include a transmission plate 320, an antenna plate 340, a dielectric plate 360, an upper plate 380, and a power source 500. The microwave application unit 300 may apply energy to the processing space 120 of the process chamber 100, and thus, may be provided as an example of a plasma source which excites a gas of the processing space 120 to plasma. The microwave application unit 300 may excite a process gas and/or a passivation gas to generate plasma. The plasma excited from the process gas may include hydrogen radical.

The transmission plate 320 may include a quartz material. In some embodiments, the transmission plate 320 may be provided as a dielectric material (for example, ceramic) such as oxide aluminum (Al₂O₃), nitride aluminum (AlN), sapphire, or nitride silicon (SiN). The transmission plate 320 may function as an upper wall of the processing space 120 and may transmit a microwave to the processing space 120. In some embodiments, an upper surface of the transmission plate 320 may have a flat plate shape. Also, a center region of a lower surface of the transmission plate 320 may be flat, and an edge region thereof may have a shape which protrudes downward. In some embodiments, a projection or a groove may be formed in a bottom center region of the transmission plate 320.

The antenna plate 340 may be disposed on the transmission plate 320. The antenna plate 340 may have a circular plate shape. In some embodiments, the antenna plate 340 may be disposed on an upper surface of the transmission plate 320 to contact the transmission plate 320. In some embodiments, the antenna plate 340 may be disposed apart from the transmission plate 320 by a certain distance. The antenna plate 340 may be provided as a metal material. According to embodiments, the antenna plate 340 may include or may be formed of copper or aluminum. Gold or silver may be plated on a surface of the antenna plate 340.

The dielectric plate 360 may be disposed on the antenna plate 340. A wavelength of a microwave may be changed by the dielectric plate 360. The dielectric plate 360 may include a quartz material. In some embodiments, the dielectric plate 360 may be provided as a dielectric material (for example, ceramic) such as oxide aluminum (Al₂O₃), nitride aluminum (AlN), sapphire, or nitride silicon (SiN). In some embodiments, the dielectric plate 360 may be provided as the same material as that of the transmission plate 320. In some embodiments, the dielectric plate 360 may be provided as a material which differs from that of the transmission plate 320. The dielectric plate 360 may have a circular plate shape. Each of an upper surface and a lower surface of the dielectric plate 360 may be provided to be flat. The dielectric plate 360 may be disposed to contact the antenna plate 340. In some embodiments, the dielectric plate 360 may be disposed apart from the antenna plate 340 by a certain distance.

The upper plate 380 may be disposed on the dielectric plate 360. The upper plate 380 may include a metal material. In some embodiments, the upper plate 380 may include an aluminum material. In some embodiments, the upper plate 380 may be provided as a cooling plate which cools the dielectric plate 360, the antenna plate 340, and the transmission plate 320. A cooling flow path 381 may be formed in the upper plate 380, and cooling water may be provided through the cooling flow path 381. The cooling water provided through the cooling flow path 381 may cool the dielectric plate 360, the antenna plate 340, and the transmission plate 320.

The power source 500 may generate a microwave. In some embodiments, the microwave generated by the power source 500 may have a frequency having a range of about 23 GHz to about 26 GHz. The microwave may be transferred through a waveguide 520. A vertical cross-sectional surface of the waveguide 520 may have a polygonal pipe shape. An inner surface of the waveguide 520 may be provided as a conductor. In some embodiments, the inner surface of the waveguide 520 may be provided as gold or silver.

A coaxial converter 540 may be disposed in the waveguide 520. The coaxial converter 540 may be disposed at a side opposite to the power source 500. One end of the coaxial converter 540 may be fixed to the inner surface of the waveguide 520. The coaxial converter 540 may have a cone shape where a cross-sectional area of a lower end is less than that of an upper end. The microwave transferred through an internal space of the waveguide 520 may have a mode converted by the coaxial converter 540 and may be propagated downward.

A mode-converted microwave may be transferred to an antenna through an external conductor 560 and an internal conductor 580. The external conductor 560 may be disposed between the waveguide 520 and the upper plate 380. In some embodiments, an upper end of the external conductor 560 may contact the waveguide 520, and a lower end of the external conductor 560 may contact the upper plate 380. A space connected with the internal space of the waveguide 520 may be formed in the external conductor 560. The internal conductor 580 may be disposed in the external conductor 560. The internal conductor 580 may be provided in a rod shape, and a length direction thereof may be arranged along a vertical direction. An outer surface of the internal conductor 580 may be disposed apart from an inner surface of the external conductor 560.

An upper end of the internal conductor 580 may be fixed to a lower end of the coaxial converter 540. The internal conductor 580 may extend in a vertical direction Z. A lower end of the internal conductor 580 may be coupled and fixed to a center of the antenna plate 340. The internal conductor 580 may be disposed to be vertical to an upper surface of the antenna plate 340. The internal conductor 580 and the external conductor 560 may be provided to be coaxial.

The microwave propagated in a vertical direction to the antenna plate 340 may be propagated in a radius direction of the dielectric plate 360, and then, may be transmitted to the processing space 120 through a slot formed in the antenna plate 340 and the transmission plate 320. The process gas supplied into the process chamber 100 may be excited to a plasma state, based on an electric field of the microwave transmitted to the processing space 120.

The heater 200 may include a body 210, a first protrusion portion 220, a second protrusion portion 230, a first embossing 211, a second embossing 221, and a third embossing 231. An upper surface of the heater 200 may be provided to have a staircase shape, based on the first protrusion portion 220 and the second protrusion portion 230. Also, an edge of an upper surface of each of the first embossing 211, the second embossing 221, and the third embossing 231 may be provided in a round shape.

Therefore, even when the heater 200 has a temperature T1 which is the temperature at which the heater 200 deforms (i.e., contracts), the heater 200 may apply heat to the entire substrate W uniformly so that temperatures of a center portion and an outer portion of the substrate W are substantially same. Therefore, a thickness of a material deposited on the substrate W may be uniform. Also, friction between a lower surface of the substrate W and the first to third embossings 211, 221, and 231 may be reduced.

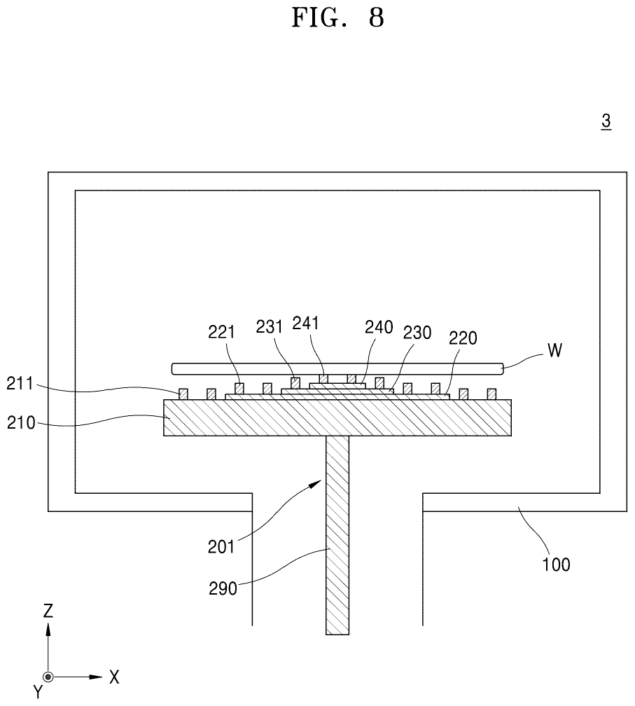

FIG. 8 is a cross-sectional view schematically illustrating a substrate processing apparatus 3 according to embodiments. Hereinafter, descriptions of the substrate processing apparatus 3 of FIG. 8, which are the same as or similar to the descriptions of the substrate processing apparatus 1 of FIG. 1, are omitted, and a difference therebetween will be mainly described.

Referring to FIG. 8, the substrate processing apparatus 3 may include a process chamber 100 and a heater 201. The heater 201 may include the body 210, the first protrusion portion 220, the second protrusion portion 230, a third protrusion portion 240, and a supporter 290.

The first embossing 211 may be formed on an upper surface of the body 210. The first embossing 211 may be formed in a region which does not overlap the first protrusion portion 220 in the vertical direction Z. The first protrusion portion 220 may have a shape which extends upward in the vertical direction Z from a center region of the body 210. The upper surface of the first protrusion portion 220 and the upper surface of the body 210 may have a step height therebetween in the vertical direction Z. The second embossing 221 may be formed on the upper surface of the first protrusion portion 220. The second embossings 221 may be formed in a region which does not overlap the second protrusion portion 230 in the vertical direction Z, on the upper surface of the first protrusion portion 220. The second embossings 221 may be formed more inward (e.g., closer to a central region of the body 210 in a horizontal direction) than the first embossings 211. The second protrusion portion 230 may have a shape which protrudes upward in the vertical direction Z from a center region of the first protrusion portion 220. The upper surface of the second protrusion portion 230 and the upper surface of the first protrusion portion 220 may have a step height therebetween in the vertical direction Z. The third embossing 231 may be formed on the upper surface of the second protrusion portion 230. The third embossings 231 may be formed in a region which does not overlap the third protrusion portion 240 in the vertical direction Z, on the upper surface of the second protrusion portion 230. The third embossings 231 may be formed more inward (e.g., closer to a central region of the body 210 in a horizontal direction) than the second embossings 221.

The third protrusion portion 240 may have a shape which protrudes upward in the vertical direction Z from a center region of the second protrusion portion 230. According to embodiments, the third protrusion portion 240 may have a circular plate shape. An upper surface of the third protrusion portion 240 may be disposed at a vertical level which is higher than the upper surface of the second protrusion portion 230. The upper surface of the third protrusion portion 240 and the upper surface of the second protrusion portion 230 may have a step height therebetween in the vertical direction Z. A footprint of the third protrusion portion 240 may be less than a footprint of the second protrusion portion 230. In the same sense, a cross-sectional area based on an X-Y plane of the third protrusion portion 240 may be less than a cross-sectional area based on an X-Y plane of the second protrusion portion 230.

A fourth embossing 241 may be formed on the upper surface of the third protrusion portion 240. The fourth embossing 241 may have a circular pillar shape which protrudes upward in the vertical direction Z from the upper surface of the third protrusion portion 240. However, a shape of the fourth embossing 241 is not limited thereto, and the fourth embossing 241 may have an angular pillar shape which extends in the vertical direction Z. According to embodiments, the fourth embossing 241 may have the same shape as that of each of the first embossing 211, the second embossing 221, and the third embossing 231. An upper surface of the fourth embossing 241 may be disposed at a vertical level which is higher than the upper surface of the third embossing 231, and a lower surface of the fourth embossing 241 may be disposed at a vertical level which is higher than the lower surface of the third embossing 231. The fourth embossing 241 may be provided in plurality. The fourth embossings 241 may be formed on the upper surface of the third protrusion portion 240. The fourth embossings 241 may be formed more inward (e.g., closer to a central region of the body 210 in a horizontal direction) than the third embossings 231. The fourth embossings 241 may be arranged apart from one another by a certain interval. The fourth embossings 241 may support the lower surface of the substrate W. A bottom region of the substrate W contacting the fourth embossings 241 may be disposed more inward (e.g., closer to a central region of the substrate W in a horizontal direction) than a bottom region of the substrate W contacting the third embossings 231. In a case where the heater 200 are configured with the first to third protrusion portions 220, 230, and 240, the lower surface of the substrate W may be uniformly supported by more precisely adjusting a step height even when thermal strain occurs in the heater 200.

Hereinabove, exemplary embodiments have been described in the drawings and the specification. Embodiments have been described by using the terms described herein, but this has been merely used for describing aspects of the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While aspects of the inventive concept have been particularly shown and described with reference to embodiments thereof, it will be understood that various changes in form and details may be made therein without departing from the spirit and scope of the following claims.

What is claimed is:

1. A substrate processing apparatus comprising:
a processing chamber including a processing space where a substrate is processed; and
a heater provided in the process chamber to support a lower surface of the substrate and configured to heat the substrate,
wherein the heater comprises a body, a first protrusion portion protruding upward in a vertical direction from a center of the body, and a second protrusion portion protruding upward in a vertical direction from a center of the first protrusion portion, and
first embossings formed in a region which does not overlap the first protrusion portion in a vertical direction on an upper surface of the body, second embossings formed in a region which does not overlap the second protrusion portion in a vertical direction on an upper surface of the first protrusion portion, and third embossings formed on an upper surface of the second protrusion portion.

2. The substrate processing apparatus of claim 1, wherein a top edge of each of the first embossings, the second embossings, and the third embossings has a round shape.

3. The substrate processing apparatus of claim 2, wherein a curvature of a round top edge of each of the first embossings, the second embossings, and the third embossings is within a range of 0.01 to 0.016.

4. The substrate processing apparatus of claim 1, wherein a step height between the first protrusion portion and the body in a vertical direction is within a range of 0.01 mm to 0.04 mm, and
a step height between the second protrusion portion and the first protrusion portion in a vertical direction is within a range of 0.01 mm to 0.04 mm.

5. The substrate processing apparatus of claim 1, wherein thicknesses of the first embossings, the second embossings, and the third embossings in a vertical direction are equal to one another.

6. The substrate processing apparatus of claim 5, wherein the thickness of each of the first embossings, the second embossings, and the third embossings in the vertical direction is within a range of 0.1 mm to 0.2 mm.

7. The substrate processing apparatus of claim 1, further comprising:
a third protrusion portion protruding in a vertical direction from a top center portion of the second protrusion portion; and
fourth embossings formed on an upper surface of the third protrusion portion.

8. The substrate processing apparatus of claim 1, wherein an upper surface of each of the first embossings, the second embossings, and the third embossings is disposed at the same vertical level with respect to a temperature T1 of the heater.

9. The substrate processing apparatus of claim 1, further comprising:
a gas supply unit configured to supply a processing gas to the processing space and a microwave application unit configured to excite the processing gas to plasma.

10. The substrate processing apparatus of claim 1, wherein a diameter of the body is within a range of 265 mm to 300 mm, and
a diameter of the first protrusion portion is within a range of 170 mm to 200 mm, and a diameter of the second protrusion portion is within a range of 100 mm to 124 mm.

11. A substrate processing apparatus comprising:
a processing chamber including a processing space where a substrate is processed;
a body provided in the process chamber to have a circular plate shape;
a first protrusion portion protruding upward in a vertical direction from a center region of the body;
a second protrusion portion protruding upward in a vertical direction from a center region of the first protrusion portion;
first embossings protruding upward in a vertical direction in a region which does not overlap the first protrusion portion in a vertical direction on an upper surface of the body;
second embossings protruding upward in a vertical direction in a region which does not overlap the second protrusion portion in a vertical direction on an upper surface of the first protrusion portion; and
third embossings protruding upward in a vertical direction from an upper surface of the second protrusion portion,
wherein an edge region of an upper surface of each of the first embossings, the second embossings, and the third embossings has a round shape.

12. The substrate processing apparatus of claim 11, wherein at least one of the body, the first protrusion portion, the second protrusion portion, the first embossings, the second embossings, and the third embossings is formed by a post-heat annealing process.

13. The substrate processing apparatus of claim 11, wherein a curvature of a round top edge of each of the first embossings, the second embossings, and the third embossings is within a range of 0.01 to 0.016.

14. The substrate processing apparatus of claim 11, further comprising:
a third protrusion portion protruding in a vertical direction from a top center portion of the second protrusion portion; and
fourth embossings formed on an upper surface of the third protrusion portion.

15. The substrate processing apparatus of claim 11, wherein a step height between the first protrusion portion and the body in a vertical direction is within a range of 0.01 mm to 0.04 mm,
a step height between the second protrusion portion and the first protrusion portion in a vertical direction is within a range of 0.01 mm to 0.04 mm, and
thicknesses of the first embossings, the second embossings, and the third embossings in a vertical direction are equal to one another.

16. The substrate processing apparatus of claim 15, wherein the thickness of each of the first embossings, the second embossings, and the third embossings in the vertical direction is within a range of 0.1 mm to 0.2 mm.

17. The substrate processing apparatus of claim 11, wherein an upper surface of each of the first embossings, the second embossings, and the third embossings is disposed at the same vertical level when a temperature of each of the body, the first protrusion portion, and the second protrusion portion is T1.

18. A substrate processing apparatus comprising:
a processing chamber including a processing space where a substrate is processed;
a heater provided in the process chamber to support a lower surface of the substrate and configured to heat the substrate;
a gas supply unit configured to supply a processing gas to the processing space;
a microwave application unit configured to excite the processing gas to plasma;
a body provided in the process chamber to have a circular plate shape;
a first protrusion portion protruding upward in a vertical direction from a center region of the body;
a second protrusion portion protruding upward in a vertical direction from a center region of the first protrusion portion;
first embossings protruding upward in a vertical direction in a region which does not overlap the first protrusion portion in a vertical direction on an upper surface of the body;
second embossings protruding upward in a vertical direction in a region which does not overlap the second protrusion portion in a vertical direction on an upper surface of the first protrusion portion; and
third embossings protruding upward in a vertical direction from an upper surface of the second protrusion portion,
wherein an edge region of an upper surface of each of the first embossings, the second embossings, and the third embossings has a round shape, and a curvature of a round top edge of each of the first embossings, the second embossings, and the third embossings is within a range of 0.01 to 0.016,
thicknesses of the first embossings, the second embossings, and the third embossings in a vertical direction are equal to one another, and
a step height between the first protrusion portion and the body in a vertical direction is within a range of 0.01 mm to 0.04 mm, and a step height between the second protrusion portion and the first protrusion portion in a vertical direction is within a range of 0.01 mm to 0.04 mm.

19. The substrate processing apparatus of claim 18, wherein a diameter of the body is within a range of 265 mm to 300 mm, and
a diameter of the first protrusion portion is within a range of 170 mm to 200 mm, and a diameter of the second protrusion portion is within a range of 100 mm to 124 mm.

20. The substrate processing apparatus of claim 18, wherein an upper surface of each of the first embossings, the second embossings, and the third embossings is disposed at the same vertical level with respect to a temperature T1 of the heater.
